(19) United States
(12) Patent Application Publication
(10) Pub. No.: US 2012/0133775 A1
(43) Pub. Date: May 31, 2012

(54) SYSTEM AND METHOD FOR DETECTING EXPLOSIVE AGENTS USING SWIR, MWIR, AND LWIR HYPERSPECTRAL IMAGING

(75) Inventors: Patrick Treado, Pittsburgh, PA (US); Charles W. Gardner, JR., Gibsonia, PA (US); Matthew Nelson, Harrison City, PA (US); Ryan Priore, Wexford, PA (US)

(73) Assignee: CHEMIMAGE CORPORATION, Pittsburgh, PA (US)

(21) Appl. No.: 13/020,997

(22) Filed: Feb. 4, 2011

Related U.S. Application Data
(63) Continuation-in-part of application No. 12/754,229, filed on Apr. 5, 2010.
Application No. 12/754,229 is a continuation-in-part of application No. 12/924,831, filed on Oct. 6, 2010.
Application No. 12/924,831 is a continuation-in-part of application No. 12/802,649, filed on Jun. 11, 2010.
(60) Provisional application No. 61/301,814, filed on Feb. 5, 2010.
(60) Provisional application No. 61/305,667, filed on Feb. 18, 2010.
(60) Provisional application No. 61/324,963, filed on Apr. 16, 2010.
(60) Provisional application No. 61/395,440, filed on May 13, 2010.
(60) Provisional application No. 61/398,213, filed on Jun. 22, 2010.
(60) Provisional application No. 61/403,141, filed on Sep. 10, 2010.
(60) Provisional application No. 61/403,329, filed on Sep. 14, 2010.
(60) Provisional application No. 61/403,331, filed on Sep. 14, 2010.
(60) Provisional application No. 61/403,330, filed on Sep. 14, 2010.
(60) Provisional application No. 61/434,034, filed on Jan. 19, 2011.
(60) Provisional application No. 61/460,816, filed on Jan. 7, 2011.
(60) Provisional application No. 61/438,723, filed on Feb. 2, 2011.

(51) Int. Cl. H01L 27/146; H04N 5/33

(52) U.S. Cl. 348/164; 250/330; 348/E05.09

(57) ABSTRACT

A system and method for hyperspectral imaging to detect hazardous agents including explosive agents. A system comprising a tunable laser, a collection optics, and one or more hyperspectral imaging detectors configured for hyperspectral imaging of a target comprising an unknown material. A method comprising illuminating a target comprising an unknown material via a tunable laser to thereby generate a plurality of interacted photons. Detecting said interacted photons to generate at least one hyperspectral image representative of the target. One or more hyperspectral images may be obtained including SWIR, MWIR, and LWIR hyperspectral images. Algorithms and chemometric techniques may be applied to assess the hyperspectral images to identify the unknown material as comprising an explosive agent or a non-explosive agent. A video imaging device may also be configured to provide a video image of an area of interest, which may be assessed to identify a target for interrogation using hyperspectral imaging.

### RELATED APPLICATIONS

This application is a continuation-in-part of U.S. patent application Ser. No. 12/754,229, filed on Apr. 5, 2010, entitled, “Chemical Imaging Explosives (CHIMED) Optical Sensor”; a continuation-in-part of U.S. patent application Ser. No. 12/924,831, filed on Oct. 6, 2010, entitled, “System and Methods for Explosives Detection using SWIR”; and a continuation-in-part of U.S. patent application Ser. No. 12/802,649, filed on Jun. 11, 2010, entitled, “Portable System for Detecting Explosives and Method for Use Thereof.” These applications are hereby incorporated by reference in their entireties.

This application also claims priority under 35 U.S.C. 119(e) to the following U.S. Provisional Patent Applications: 61/301,814, filed on Feb. 5, 2010, entitled “System and Method for Detecting Hazardous Agents Including Explosives”; 61/305,667, filed on Feb. 18, 2010, entitled “System and Method for Detecting Explosives on Shoes and Clothing”; 61/324,963, filed on Apr. 16, 2010, entitled “Short-Wavelength Infrared (SWIR) Multi-Conjugate Liquid Crystal Tunable Filter”; 61/395,440, filed on May 13, 2010, entitled, “Portable System for Detecting Explosives and Methods for Use Thereof”; 61/398,213, filed on Jun. 22, 2010, entitled “VIPIR Near Infrared HSLx Homemade Explosives Detector”; 61/403,141, filed on Sep. 10, 2010, entitled “Systems and Methods for Improving Imaging Technology”; 61/403,329, filed on Sep. 14, 2010, entitled “Hyperspectral Sensor for Tracking Moving Targets”; 61/403,331, filed on Sep. 14, 2010, entitled “Cognitive Multi-Sensor Improvised Explosive Devices Detection Techniques (COMIDT)”; 61/403,330, filed on Sep. 14, 2010, entitled “System and Method for Object Tracking”; U.S. Patent Provisional Patent Application No. 61/434,034, filed on Jan. 19, 2011, entitled “VIS-SNIR Multi-Conjugate Tunable Filter”; U.S. Provisional Patent Application No. 61/460,816, filed on Jan. 7, 2011, entitled “Conformal Filter and Method for Use Thereof”; and U.S. Provisional Patent Application No. 61/438,723, filed on Feb. 2, 2011, entitled “System and Method for Hyperspectral Imaging and Data Analysis During Surgery.” These applications are hereby incorporated by reference in their entireties.

### BACKGROUND

Spectroscopic imaging combines digital imaging and molecular spectroscopy techniques, which can include Raman scattering, fluorescence, photoluminescence, ultraviolet, visible and infrared absorption spectroscopies. When applied to the chemical analysis of materials, spectroscopic imaging is commonly referred to as chemical imaging. Instruments for performing spectroscopic (i.e. chemical) imaging typically comprise an illumination source, image gathering optics, focal plane array imaging detectors and imaging spectrometers.

In general, the sample size determines the choice of image gathering optic. For example, a microscope is typically employed for the analysis of sub micron to millimeter spatial dimension samples. For larger objects, in the range of millimeter to meter dimensions, macro lens optics are appropriate. For samples located within relatively inaccessible environments, flexible fiberscope or rigid borescopes can be employed. For very large scale objects, such as planetary objects, telescopes are appropriate image gathering optics.

For detection of images formed by the various optical systems, two-dimensional, imaging focal plane array (FPA) detectors are typically employed. The choice of FPA detector is governed by the spectroscopic technique employed to characterize the sample of interest. For example, silicon (Si) charge-coupled device (CCD) detectors or CMOS detectors are typically employed with visible wavelength fluorescence and Raman spectroscopic imaging systems, while indium gallium arsenide (InGaAs) FPA detectors are typically employed with near-infrared spectroscopic imaging systems.

Spectroscopic imaging of a sample can be implemented by one of two methods. First, a point-source illumination can be provided on the sample to measure the spectra at each point of the illuminated area. Second, wide-field spectroscopic imaging of a sample can be implemented by collecting spectra over the entire area encompassing the sample simultaneously using an electronically tunable optical imaging filter such as an acousto-optic tunable filter (AOTF) or a liquid crystal tunable filter (“LCTF”). Here, the organic material in such optical filters are actively aligned by applied voltages to produce the desired bandpass and transmission function. The spectra obtained for each pixel of such an image thereby forms a complex data set referred to as a hyperspectral image which contains the intensity values at numerous wavelengths or the wavelength dependence of each pixel element in this image.

Spectroscopic devices operate over a range of wavelengths due to the operation ranges of the detectors or tunable filters possible. This enables analysis in the Ultraviolet (UV), visible (VIS), near infrared (NIR), short-wave infrared (SWIR), mid infrared (MIR) wavelengths, long wave infrared wavelengths (LWIR), and to some overlapping ranges. These correspond to wavelengths of approximately 180-380 nm (UV), 380-700 nm (VIS), 700-2500 nm (NIR), 850-1800 nm (SWIR), 650-1100 nm (MWIR), 400-1100 (VIS-NIR) and 1200-2450 (LWIR).

There currently exists a need for accurate detection of explosive agents. In particular, there exists a need for accurate and reliable detection of explosive agents in standoff and on-the-move (OTM) configurations for both daytime and nighttime operations.

### SUMMARY OF THE INVENTION

The present disclosure relates to systems and methods for detecting explosive agents using spectroscopic methods, including imaging. More specifically, the present disclosure provides for systems and methods for explosive detection using short wave infrared (“SWIR”), mid wave infrared (“MWIR”), and long wave infrared (“LWIR”) hyperspectral imaging using a tunable laser. The present disclosure provides for systems and methods that that may operate using both passive and active illumination modalities and may. Therefore, the systems and methods disclosed herein hold potential or daytime and nighttime configurations.

### BRIEF DESCRIPTION OF THE DRAWINGS

The accompanying drawings, which are included to provide further understanding of the disclosure and are incorporated in and constitute a part of this specification, illustrate embodiments of the disclosure and, together with the description, serve to explain the principles of the disclosure.

In the drawings:

FIG. 1 is illustrative of a system of the present disclosure.

FIG. 2 is illustrative of a system of the present disclosure.

FIG. 3 is representative of an algorithm of the present disclosure.

FIG. 4 is representative of a method of the present disclosure.

### DETAILED DESCRIPTION

Reference will now be made in detail to the preferred embodiments of the present disclosure, examples of which are illustrated in the accompanying drawings. Wherever possible, the same reference numbers will be used throughout the drawings to refer to the same or like parts.

The present disclosure provides for a system and method for detecting hazardous agents, including explosive agents. These explosive materials may be present on or in a target. The target may include, but is not limited to: a location on a vehicle, a vehicle as a whole, a package, a human hand, a passport, a credit card, a driver's license, a boarding pass, a human body part, a piece of human clothing, a human-wearable item, shoes, an airline ticket, baggage, and other items that may have come in contact with a human being. The present disclosure contemplates the target may comprise any item that may need to be scanned for explosive agents to ensure the safety of an area. Additionally, the target may be present in a region of interest of either an indoor or outdoor scene. The technology described herein may be used to detect Improvised Explosive Devices (LEDs), emplacements (such as DE and aged concrete), command wires, EFP wires, disturbed earth, EFP camouflage, and explosive residue, among other materials including but not limited to those associated with explosive compounds and concealments.

Explosive agents, as referred to herein, may include explosive compounds, a residue of an explosive compound, a formulation additive of explosive material, and/or a binder of explosive material. Representative explosive compounds may include but are not limited to: nitrocellulose, Ammonium nitrate (“AN”), nitroglycerin, 1,3,5-trinitroperhydro-1,3,5-triazine (“RDX”), 1,3,5,7-tetranitroperhydro-2,3,5,7-tetrazocine (“HMX”) and 1,3,-Dinitrato-2,2-bis (nitratomethyl)propane (“PETN”). The system and method herein may be used for anomaly detection, countermine research and camouflage concealment and detection through measurements taken from a ground vehicle or aerial vehicle. The invention may be deployed either on a user's vehicle, an unmanned ground vehicle (“UGV”) traveling ahead of them, or an aerial vehicle performing a wide range of surveillance tasks. The present disclosure contemplates that they system and method herein may be applied to other detection scenarios including chemical, biological, a biohazard or an illegal drug.

In one embodiment, the system and method of the present disclosure may operate in a scanning mode, scanning an area of interest to identify a target for interrogation. In another embodiment, the system and method of the present disclosure may operate in a detection mode, interrogating a target comprising an unknown material to identify whether or not an explosive or other hazardous agent is present. The present disclosure also contemplates that the system and method may be configured to operate in a combination scanning/detection configuration. These scanning and detection modes may be operated either sequentially or simultaneously. Simultaneous acquisition of multiple types of data may be accomplished using structured illumination or different light sources.

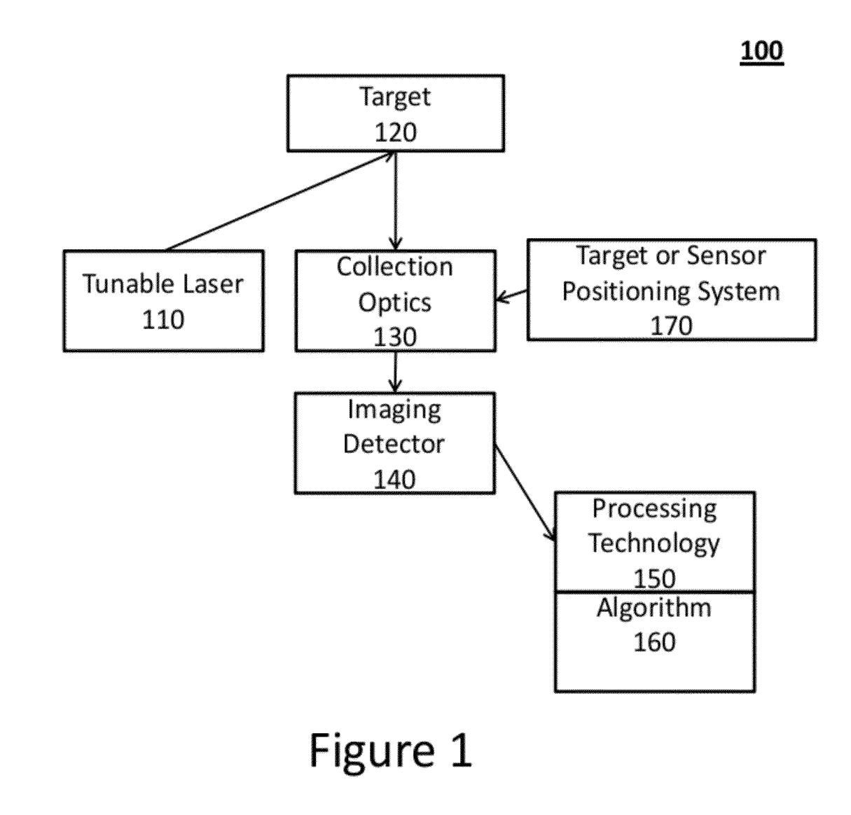

FIG. 1 is illustrative of a system of the present disclosure. The system may be configured for standoff detection of hazardous agents. In such a configuration, the system may operate in a stationary or on-the-move modality. The system may be mounted on a movable vehicle including but not limited to a car, truck, tank, boat, plane, or other means of transportation.

In one embodiment, the system 100 comprises a tunable laser 110 configured so as to sequentially illuminate a target comprising an unknown material 120 with a plurality of predetermined wavelengths of light to thereby generate a plurality of interacted photons. In such an embodiment, the system does not require a spectral encoding or spectral dispersive device because the wavelength selection is accomplished via the tunable laser. These interacted photons may comprise photons selected from the group consisting of: photons scattered by the sample, photons absorbed by the sample, photons reflected by the sample, photons transmitted by the sample, photons luminance by the sample, and combinations thereof.

In another embodiment, the illumination source 110 may further comprise a passive illumination source. The passive illumination source may be solar radiation (the sun) or ambient light. In another embodiment, both active and passive illumination may be used.

These interacted photons may be collected by one or more collection optics 130. This collection optics 130 may comprise at least one telescope optic, zoom optic, fixed optic, macro/micro combination optic (also referred to herein as a “combination optic”), and combinations thereof. The system of the present disclosure contemplates that it one embodiment, two or more collection optics may be configured so as to collect interacted photons for assessment in two or more different modalities.

At least one imaging detector 140 may detect the plurality of interacted photons and generate at least one hyperspectral image representative of the target. In one embodiment, the detector may generate at least one hyperspectral image selected from the group consisting of: a SWIR hyperspectral image, a MWIR hyperspectral image, a LWIR hyperspectral image, and combinations thereof. In one embodiment, the imaging detector 140 may comprise a detector selected from the group consisting of: an InGaAs detector, an extended range InGaAs detector, an InSb detector, a microbolometer, a PtSi detector and combinations thereof.

In another embodiment, the system 100 may further comprise one or more additional imaging devices to enable the system to operate in multiple modes. In one embodiment, the system 100 may further comprise a video imaging device, which may be a RGB video imaging device, configured so as to output a video image representative of an area of interest comprising the target. This video image may be a dynamic video image, configured for real-time operation in various modes including standoff, stationary, and on-the-move. This video imaging device may also enable the system of the present disclosure to operate in a scanning mode, scanning an area of interest to identify a target for further interrogation using hyperspectral imaging. In such an embodiment, a user may monitor the video image and identify a target based on at least one of: size, shape, and color of the target. A means for assessing the video image may comprise morphological analysis by a user which may be accomplished by at least one of: visual inspection by user, applying an algorithm, and applying a chemometric technique. Once the target is identified, it may be assessed using hyperspectral imaging to determine whether or not it is a hazardous agent.

The system 100 may further comprise a means for assessing the hyperspectral image obtained. In one embodiment, processing technology 150 may be configured to assess the hyperspectral image. In one embodiment, the processing technology 150 may comprise a processor such as a single board PC. Other embodiments may contemplate the use of other processing technology including HyperX and PhysX. To assess the hyperspectral image, the processing technology 150 may be configured so as to apply one or more algorithms 160 including but not limited to: object imaging and tracking, image weighted Bayesian fusion (“IMBF”), simultaneous location and mapping (“SLAM”), scale-invariant feature transform (“SIFT”), hybrid false color, and combinations thereof.

The system 100 may also be configured so as to utilize one or more targeting or sensor positioning systems 170. This may include the use of one or more of a pan tilt unit and a global positioning system (“GPS”). Other targeting or sensor positioning systems contemplated by the present disclosure may include, but are not limited to: a laser range finger, light detection and ranging (“LIDAR”), stereovision, and thermal imaging.

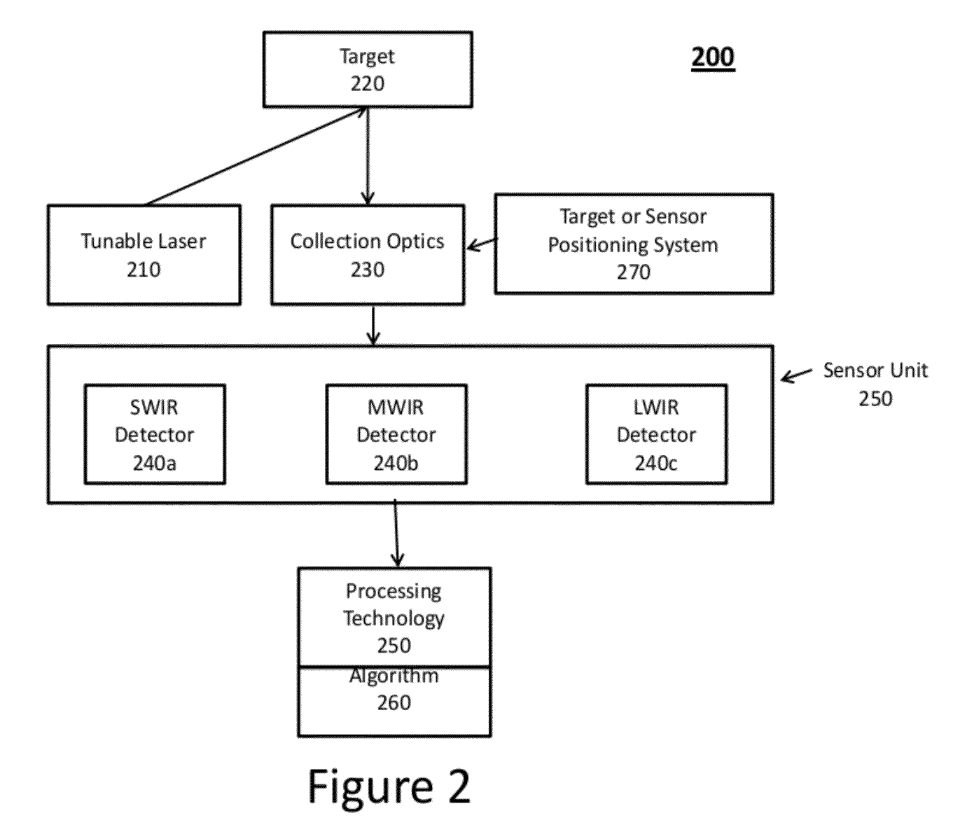

The present disclosure also provides for a multi-mode system configured to interrogate a target using two or more different hyperspectral imaging devices. One embodiment of such a system is illustrated by FIG. 2. In FIG. 2, the system 200 provides for a tunable laser 210 configured to sequentially illuminate a target comprising an unknown material 220 to thereby generate a plurality of interacted photons. These photons may be collected by one or more collection optics 230. A first imaging detector may comprise a SWIR detector 240a configured to generate SWIR data representative of the target. This SWIR data may comprise at least one of a SWIR spectra, a SWIR image, and combinations thereof. In one embodiment, this SWIR data may comprise a SWIR hyperspectral image representative of the target. In one embodiment, the SWIR detector 240a may comprise at least one of an InGaAs detector, an extended range InGaAs detector, and combinations thereof.

The system 200 may further comprise a second imaging detector. This second imaging detector may comprise a MWIR detector 240b configured to generate MWIR data representative of the target. This data may comprise at least one of a MWIR spectra, a MWIR image, and combinations thereof. In one embodiment, the MWIR data may comprise a MWIR hyperspectral image representative of the target. In one embodiment, the MWIR detector 240b, may comprise at least one of: an InSb detector, a PtSi detector, and combinations thereof.

The system 200 may further comprise a third imaging detector. This third imaging detector may comprise a LWIR detector 240c configured to generate LWIR data representative of the target. This data may comprise at least one of a LWIR spectra, a LWIR image, and combinations thereof. In one embodiment, this data may comprise a LWIR hyperspectral image representative of the target. In one embodiment, the LWIR detector 240c may comprise a microbolometer. The SWIR detector 240a, the MWIR detector 240b, and the LWIR detector 240c, may be housed in a sensor unit 250.

The system 200 may further comprise a means for directing one or more subsets of said interacted photons to one or more appropriate detectors for hyperspectral imaging in various modalities. In one embodiment, this direction may be accomplished using one or more directing elements such as a mirror, a lens, a beamsplitter, and others known in the art. In another embodiment, detection may be accomplished by collecting all photons received at one or more collection optics without redirecting subsets of said photons to a particular detector.

The system 200 may further comprise a means for assessing the hyperspectral data generated. In such an embodiment, processing technology 250 may be configured to assess one or more hyperspectral images. This processing technology 250 may comprise a single board PC. Other embodiments may contemplate the use of other processing technology including HyperX and PhysX.

To assess the hyperspectral images, the processing technology 250 may be configured so as to apply one or more algorithms 260 including but not limited to: object imaging and tracking, image weighted Bayesian fusion (“IMBF”), simultaneous location and mapping (“SLAM”), scale-invariant feature transform (“SIFT”), hybrid false color, and combinations thereof.

The system 200 may also be configured so as to utilize one or more targeting or sensor positioning systems 270. This may include the use of one or more of a pan tilt unit and a global positioning system (“GPS”). Other targeting or sensor positioning systems contemplated by the present disclosure may include, but are not limited to: a laser range finger, light detection and ranging (“LIDAR”), stereovision, and thermal imaging.

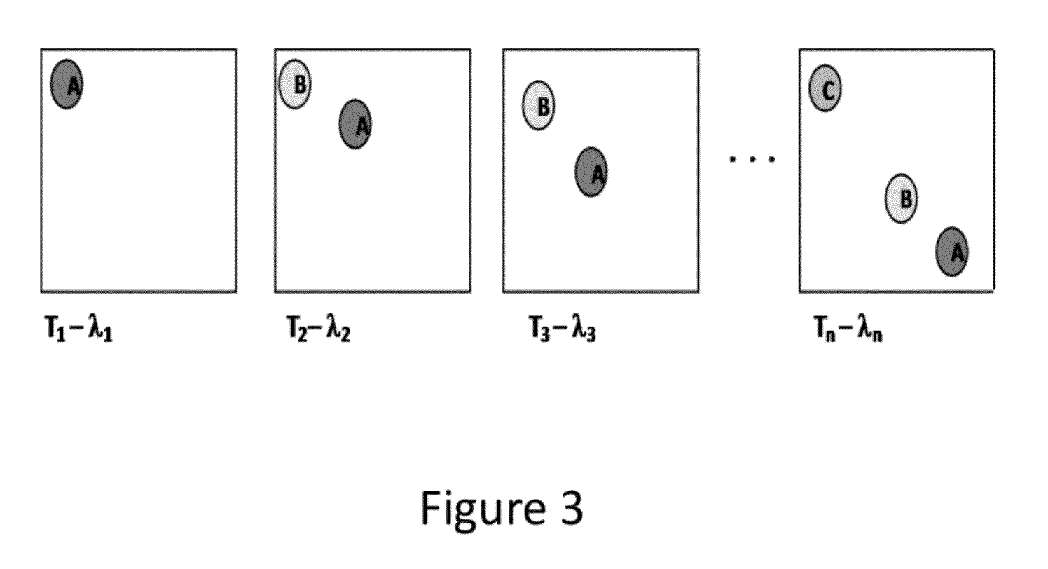

FIG. 3 is representative of an object imaging and tracking methodology which is contemplated by the present disclosure. In FIG. 3, object A is present in a slightly translated position in every frame, with each frame collected at a different wavelength. The tracking of object A across all n frames allows the spectrum to be generated for every pixel in the object. The same process may be followed for objects B and C. The same process may be followed for n number of objects in a scene. A continual stream of objects may be imaged with defined wavelengths at defined time intervals. Such a methodology may provide the benefit of signal averaging.

One embodiment may comprise the use of hyperspectral addition imaging, more fully described in U.S. patent application Ser. No. 12/799,779, filed on Apr. 30, 2010, entitled “System and Method for Component Discrimination Enhancement Based on Multispectral Addition Imaging,” which is hereby incorporated by reference in its entirety. The present disclosure also contemplates the use of one or more chemometric techniques for assessing hyperspectral images. These techniques may be applied to compare test data generated by interrogating a target to reference data corresponding to known samples. This reference data may be stored in a reference data base. In one embodiment, a processing technology 160 may be configured to execute a machine readable program code to search a reference database.

Chemometric techniques may include, but are not limited to: principal component analysis (“PCA”), multivariate curve resolution (“MCR”), partial least squares discriminant analysis (“PLSDA”), k means clustering, band t. entropy method, adaptive subspace detector, cosine correlation analysis (“CCA”), Euclidian distance analysis (“EDA”), partial least squares regression (“PLSR”), spectral mixture resolution (“SMR”), a spectral angle mapper metric, a spectral information divergence metric, a Mahalanobis distance metric, a spectral unmixing algorithm, and combinations thereof. A spectral unmixing metric is disclosed in U.S. Pat. No. 7,072,770 entitled “Method for Identifying Components of a Mixture via Spectral Analysis,” which is hereby incorporated by reference in its entirety.

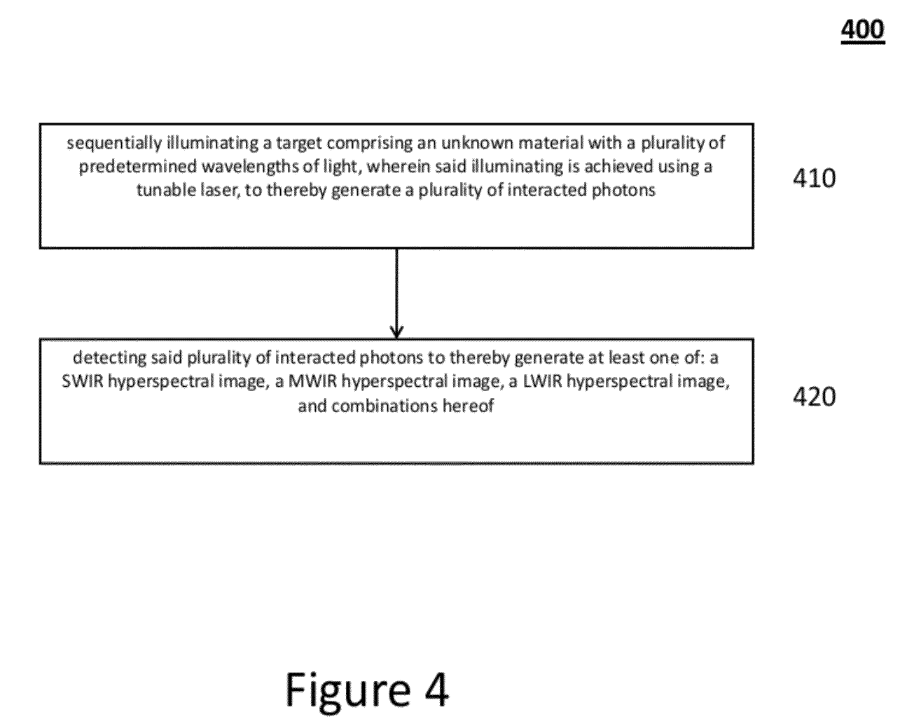

The present discourse also provides for a method, one embodiment of which is represented by FIG. 4. The method 400 comprises sequentially illuminating a target comprising an unknown material with a plurality of predetermined wavelengths of light in step 410. In one embodiment, said illuminating is achieved using a tunable laser, to thereby generate a plurality of interacted photons. These interacted photons may be detected in step 420 to thereby generate at least one of: a SWIR hyperspectral image, a MWIR hyperspectral image, a LWIR hyperspectral image, and combinations thereof.

In one embodiment, the method 400 may provide for detection using two or more modalities. In one embodiment, SWIR and MWIR hyperspectral images may be generated. In another embodiment, MWIR and LWIR hyperspectral images may be generated. In yet another embodiment, SWIR, MWIR, and LWIR hyperspectral images may be generated.

The present disclosure contemplates that the system and method disclosed herein may be configured for multi-mode detection using either sequential or simultaneous data acquisition.

In another embodiment of method 400, the hyperspectral image generated in step 420 may be assessed to thereby identify the unknown material as at least one of an explosive agent and a non-explosive agent. In one embodiment, this assessment may comprise applying at least one algorithm including: object imaging and tracking, image weighted Bayesian fusion, simultaneous location and mapping, scale-invariant feature transform, hybrid false color, and combinations thereof. This assessment may also be achieved by applying one or more chemometric techniques.

The system and method of the present disclosure also contemplate the use of sensor fusion which may hold potential for increasing the accuracy and reliability of explosive detection. In such an embodiment, processing technology may be configured so as to fuse data from two or more detectors. In one embodiment, sensor fusion may comprise Forensic Integrated Search Technology (“FIST”) available from ChemImage Corporation, Pittsburgh, Pa. This technology is more fully described in the following U.S. patent applications, hereby incorporated by reference in their entireties: U.S. patent application Ser. No. 11/450,138, filed on Jun. 9, 2006, entitled “Forensic Integrated Search Technology”; U.S. patent application Ser. No. 12/017,445, filed on Jan. 22, 2008, entitled “Forensic Integrated Search Technology with Instrument Weight Factor Determination”; and U.S. patent application Ser. No. 12/339,805, filed on Dec. 19, 2008, entitled “Detection of Pathogenic Microorganisms Using Fused Sensor Data.”

The present disclosure may be embodied in other specific forms without departing from the spirit or essential attributes of the disclosure. Accordingly, reference should be made to the appended claims, rather than the foregoing specification, as indicating the scope of the disclosure. Although the foregoing description is directed to the embodiments of the disclosure, it is noted that other variations and modification will be apparent to those skilled in the art, and may be made without departing from the spirit or scope of the disclosure.

What is claimed is:

1. A system comprising:
a tunable laser illumination source configured so as to sequentially illuminate a target comprising an unknown material with a plurality of predetermined wavelengths of light to thereby generate a plurality of interacted photons;
a collection optics, configured so as to collect said plurality of interacted photons;
at least one imaging detector, configured so as to detect said plurality of interacted photons and generate at least one of: a SWIR hyperspectral image representative of said target, a MWIR hyperspectral image representative of said target, a LWIR hyperspectral image representative of said target, and combinations thereof.

2. The system of claim 1 further comprising a passive illumination source.

3. The system of claim 2 wherein said passive illumination source comprises a solar illumination source.

4. The system of claim 1 wherein said collection optics comprises at least one optic selected from the group consisting of: a telescopic optic, a fixed optic, a zoom optic, a combination optic, and combinations thereof.

5. The system of claim 1 wherein said at least one imaging device comprises at least one of: an InGaAs detector, an extended range InGaAs detector, an InSb detector, a microbolometer, a PtSi detector, and combinations thereof.

6. The system of claim 1 further comprising a video imaging device configured so as to generate a video image representative of an area of interest, wherein said area of interest comprises said target.

7. The system of claim 6 wherein said video imaging device comprises a RGB video imaging device.

8. The system of claim 1 further comprising a means for assessing at least one of said SWIR hyperspectral image, said MWIR hyperspectral image, said LWIR hyperspectral image, and combinations thereof, to thereby identify said unknown material as at least one of: an explosive agent and a non-explosive agent.

9. The system of claim 6 further comprising a means for assessing said video image representative of said area of interest to thereby identify a target.

11. A method comprising:
sequentially illuminating a target comprising an unknown material with a plurality of predetermined wavelengths of light, wherein said illuminating is achieved using a tunable laser, to thereby generate a plurality of interacted photons; and
detecting said plurality of interacted photons to thereby generate at least one of: a SWIR hyperspectral image, a MWIR hyperspectral image, a LWIR hyperspectral image, and combinations hereof.

12. The method of claim 11 further comprising assessing at least one of said SWIR hyperspectral image, said MWIR hyperspectral image, said LWIR hyperspectral image, and combinations thereof to thereby identify said unknown material as at least one of: an explosive agent and a non-explosive agent.

13. The method of claim 12 wherein said assessing is achieved by applying at least one algorithm selected from the group consisting of: object imaging and tracking, image weighted Bayesian fusion, simultaneous location and mapping, scale-invariant feature transform, hybrid false color, and combinations thereof.

14. The method of claim 11 wherein said detecting further comprises:
detecting a first subset of said plurality of interacted photons at a first imaging detector to thereby generate at least one SWIR hyperspectral image representative of said target;
detecting a second subset of said plurality of interacted photons at a second imaging detector to thereby generate at least one MWIR hyperspectral image representative of said target; and
detecting a third subset of said plurality of interacted photons at a third imaging detector to thereby generate at least one LWIR hyperspectral image representative of said target.

15. The method of claim 12 wherein said assessing is achieved by applying at least one chemometric technique.

16. The method of claim 11 further comprising generating at least one video image representative of an area of interest, wherein said area of interest comprises said target.

17. The method of claim 16 wherein said video image comprises a RGB video image.

18. A system comprising:
a tunable laser illumination source configured so as to sequentially illuminate a target comprising an unknown material with a plurality of predetermined wavelengths of light to thereby generate a plurality of interacted photons;
a collection optics for collecting said plurality of interacted photons;
a first imaging detector configured so as to detect a first subset of said plurality of interacted photons to thereby generate a SWIR hyperspectral image representative of said target;
a second imaging detector configured so as to detect a second subset of said plurality of interacted photons to thereby generate a MWIR hyperspectral image representative of said target;
a third imaging detector configured so as to detect a third subset of said plurality of interacted photons to thereby generate a LWIR hyperspectral image representative of said target.

19. The system of claim 18 further comprising a means for directing said first subset of interacted photons to said first imaging detector.

20. The system of claim 18 further comprising a means for directing said second subset of interacted photons to said second imaging detector.

21. The system of claim 18 further comprising a means for directing said third subset of interacted photons to said third imaging detector.

22. The system of claim 18 wherein said first imaging detector comprises a detector selected from the group consisting of: an InGaAs detector, an extended range InGaAs detector, and combinations thereof.

23. The system of claim 18 wherein said second imaging detector comprises a detector selected from the group consisting of: an InSb detector, a PtSi detector, and combinations thereof.

24. The system of claim 18 wherein said third imaging detector comprises a microbolometer.

25. The system of claim 18 wherein said collection optics comprises at least one optic selected from the group consisting of: a telescope optic, a fixed optic, a zoom optic, a combination optic, and combinations thereof.

26. The system of claim 18 further comprising a fourth imaging detector, wherein said fourth imaging detector comprises a video imaging device configured to generate a video image representative of an area of interest, wherein said area of interest comprises said target.

27. The system of claim 26 wherein said video imaging device comprises a RGB video imaging device.

28. The system of claim 18 further comprising a means for assessing at least one of: said SWIR hyperspectral image, said MWIR hyperspectral image, said LWIR hyperspectral image, and combinations thereof, to thereby identify said unknown material as at least one of: an explosive agent and a non-explosive agent.

29. The system of claim 26 further comprising a means for assessing said video image representative of said area of interest to thereby identify said target.
